(19) United States
(12) Patent Application Publication
(10) Pub. No.: US 2026/0271145 A1
(43) Pub. Date: Sep. 10, 2026

(54) POWER SUPPLY CIRCUIT AND LAMP

(71) Applicant: FILAMENT LIGHTING LLC, San Jose, CA (US)

(72) Inventor: Dengfeng He, Xi'an (CN)

(21) Appl. No.: 19/241,016

(22) Filed: Jun. 17, 2025

(30) Foreign Application Priority Data
Mar. 5, 2025 (CN) 2025102529959

(51) Int. Cl. H05B 41/285; H05B 41/28

(52) U.S. Cl. CPC H05B 41/2853; H05B 41/2813

(57) ABSTRACT

A power supply circuit and a lamp are disclosed. The power supply circuit includes an input port, an output port, a power factor correction (PFC) module and a ballast detection module. The input port is connected to the power supply and to a load. Both ends of the PFC module are connected to the input port and the output port respectively. The ballast detection module is connected to the PFC module, it turns off the PFC module to be in an inactive state when detecting that a ballast is connected to the power supply circuit, and turns on the PFC module to be in an active state when detecting that no ballast is connected to the power supply circuit.

### CROSS-REFERENCE TO RELATED APPLICATION

This application is based on and claims the benefit of priority from Chinese Patent Application No. 2025102529959, filed on Mar. 5, 2025, the entirety of which is incorporated by reference herein.

### TECHNICAL FIELD

The embodiments of the present disclosure relate to the field of power supply for lamps, and in particular, to a power supply circuit and a lamp.

### BACKGROUND

In the application environment of lamps, the access methods of lamps mainly include direct access to mains supply and access to mains supply through ballasts. When the power supply circuit of the lamp is connected to a ballast, the ballast will generate a high voltage when it is started. The high voltage generated by the ballast can easily cause damage to the power factor correction (PFC) circuit.

### SUMMARY

The following is an overview of the subject matter described in detail herein. This summary is not intended to limit the scope of the claims.

An objective of the present disclosure is to solve one of the technical problems in the existing technology at least to some extent. The embodiments of the present disclosure provide a power supply circuit and a lamp that can reduce the damage to the PFC circuit caused by the high voltage generated by the ballast.

According to an embodiment of a first aspect of the present disclosure, a power supply circuit is provided, including:

an input port configured to be connected to a power supply;

an output port configured to be connected to a load;

a PFC module, both ends of the PFC module being connected to the input port and the output port respectively; and

a ballast detection module connected to the PFC module, the ballast detection module being configured to turn off the PFC module to be in an inactive state in response to detecting that a ballast is connected to the power supply circuit, and turn on the PFC module to be in an active state in response to detecting that no ballast is connected to the power supply circuit.

According to some embodiments of a first aspect of the present disclosure, the ballast detection module includes a filter unit and a first comparison unit. Both ends of the filter unit are connected to the input port and the first comparison unit respectively. The filter unit is configured to filter an input electrical signal of the input port to obtain a filtered electrical signal. The first comparison unit is configured to compare the filtered electrical signal with the input electrical signal to obtain a first comparison signal, and the first comparison signal is configured to indicate whether the ballast is connected to the power supply circuit.

According to some embodiments of the first aspect of the present disclosure, the ballast detection module includes a first peak detection unit, an integration unit and a second comparison unit. Both ends of the first peak detection unit are connected to the input port and the second comparison unit respectively. Both ends of the integration unit are connected to the input port and the second comparison unit respectively. The first peak detection unit is configured to detect a first peak value of an input electrical signal of the input port. The integration unit is configured to integrate the input electrical signal of the input port to obtain a first integrated value. The second comparison unit is configured to compare the first peak value with the first integrated value to obtain a second comparison signal, and the second comparison signal is configured to indicate whether the ballast is connected to the power supply circuit.

According to some embodiments of the first aspect of the present disclosure, the ballast detection module includes a first calculation unit and a third comparison unit. The first calculation unit is configured to perform Fourier calculation on a sampling signal of an input electrical signal of the detection input port to obtain a harmonic content proportion value. The third comparison unit is configured to compare the harmonic content proportion value with the preset first thresholds to obtain a third comparison signal, and the third comparison signal is configured to indicate whether the ballast is connected to the power supply circuit.

According to some embodiments of the first aspect of the present disclosure, the ballast detection module includes a second peak detection unit, a timing unit and a fourth comparison unit. The second peak detection unit is configured to detect a second peak value of an input electrical signal of the input port. The timing unit is configured to calculate a duration of the second peak value. The fourth comparison unit is configured to compare the duration with a preset second threshold to obtain a fourth comparison signal, and the fourth comparison signal is configured to indicate whether the ballast is connected to the power supply circuit.

According to some embodiments of the first aspect of the present disclosure, an output end of the ballast detection module is connected to a power input end of the PFC module. In response to detecting that the ballast is connected to the power supply circuit, the output end of the ballast detection module outputs a first control level to turn off the PFC module.

According to some embodiments of the first aspect of the present disclosure, an output end of the ballast detection module is connected to a feedback end of the PFC module; in response to detecting that the ballast is connected to the power supply circuit, the output end of the ballast detection module outputs a second control level to change a voltage of the feedback end of the PFC module to turn off the PFC module.

According to some embodiments of the first aspect of the present disclosure, the ballast detection module includes a sequential logic unit connected to the PFC module, the sequential logic unit is configured to output a start timing signal in response to receiving a power-on signal, and the start timing signal is configured to control a start time of the PFC module.

According to some embodiments of the first aspect of the present disclosure, the PFC module is provided with a buffer capacitor, and the buffer capacitor is configured to clamp a voltage output by the ballast in response to the ballast being connected to the power supply circuit.

According to an embodiment of a second aspect of the present disclosure, a lamp is provided, including a light source and the power supply circuit as described in the embodiment of the first aspect of the present disclosure, where the light source is connected to an output port of the power supply circuit.

The above solution has at least the following beneficial effects: the ballast detection module turns off the PFC module to be in an inactive state when detecting that the ballast is connected to the power supply circuit, and turns on the PFC module to be in an active state when detecting that no ballast is connected to the power supply circuit. By turning off the PFC module, when the ballast is connected to the power supply circuit, damage caused by the high voltage generated by the ballast during startup to the PFC module can be avoided, and the loss of the PFC module can be reduced.

### BRIEF DESCRIPTION OF DRAWINGS

The accompanying drawings are configured to provide a further understanding of the technical scheme of the present disclosure, and constitute a part of the specification. They are used to explain the technical scheme of the present disclosure together with the embodiments of the present disclosure, and do not constitute a limitation of the technical solution of the present disclosure.

FIG. 1 is a connection diagram of a power supply circuit, a power supply, a ballast and a load.

FIG. 2 is a connection diagram of a power supply circuit, a power supply and a load.

FIG. 3 is a structural diagram of a power supply circuit.

FIG. 4 is a circuit diagram of a ballast detection module including a filter unit and a first comparison unit provided by an embodiment of the present disclosure.

FIG. 5 is a circuit diagram of the ballast detection module including a first peak detection unit, an integration unit and a second comparison unit.

FIG. 6 is a structural diagram of a first calculation unit and a third comparison unit.

FIG. 7 is a structural diagram of a second peak detection unit, a timing unit and a fourth comparison unit.

FIG. 8 is a circuit diagram of the ballast detection module including a microcontroller.

FIG. 9 is a circuit diagram of the ballast detection module, where the output end thereof is connected to the power input end of the PFC module.

FIG. 10 is a circuit diagram of the ballast detection module, where the output end thereof is connected to the feedback end of the PFC module.

FIG. 11 is a structural diagram of the timing unit and PFC module of the ballast detection module.

FIG. 12 is a structural diagram of the lamp.

### DETAILED DESCRIPTION

In order to make the objective, technical scheme and advantages of the present disclosure clear, the present disclosure will be further described in detail below with reference to the accompanying drawings and embodiments. It should be understood that the specific embodiments described here are only used to explain the present disclosure and are not used to limit the present disclosure.

It should be noted that although the functional modules are divided in the device schematic diagram and the logical sequence is shown in the flow chart. In some cases, the modules can be divided into different modules in the device or the steps can be performed as shown or described in the order of the flow chart. The terms "first", "second", etc. in the description, claims or the above-mentioned accompanying drawings are used to distinguish similar objects, and are not necessarily used to describe a specific order or sequence.

The embodiments of the present disclosure provide a power supply circuit and a lamp.

The embodiments of the present disclosure will be further described below with reference to the accompanying drawings.

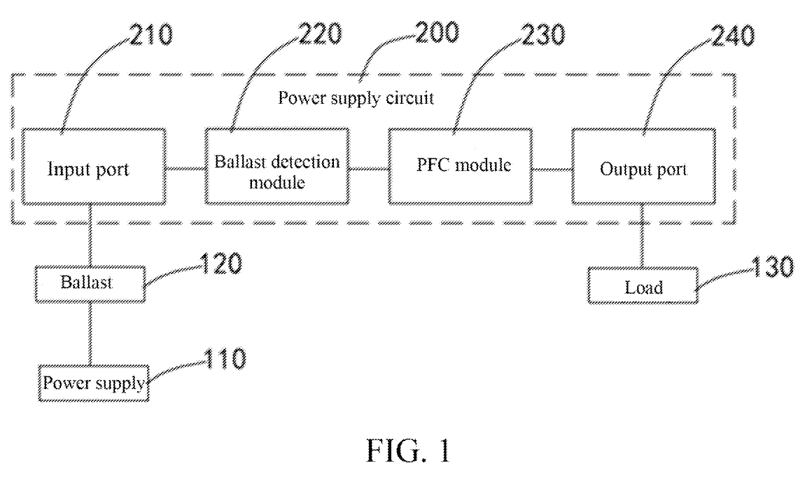

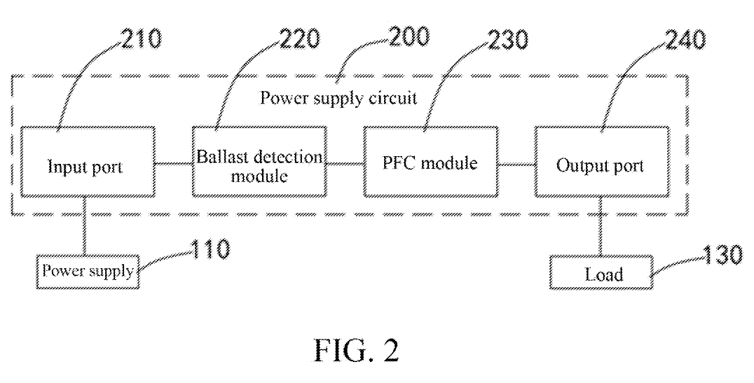

Referring to FIG. 1 and FIG. 2, the power supply circuit 200 includes an input port 210, an output port 240, a power factor correction (PFC) module 230 and a ballast detection module 220.

The input port 210 is configured to be connected to the power supply 110, and the output port 240 is configured to be connected to a load 130. Both ends of the PFC module 230 are connected to the input port 210 and the output port 240 respectively. The ballast detection module 220 is connected to the PFC module 230. The ballast detection module 220 is configured to turn off the PFC module 230 to be in an inactive state when detecting that a ballast 120 is connected to the power supply circuit 200, and turn on the PFC module 230 to be in an active state when detecting that no ballast 120 is connected to the power supply circuit 200.

FIG. 1 is a schematic diagram of a power supply circuit 200 connected to a ballast 120, and an input port 210 of the power supply circuit is connected to a power supply 110 via the ballast 120. FIG. 2 is a schematic diagram of the power supply circuit 200 without connecting the ballast 120, and the input port 210 of the power supply circuit is directly connected to the power supply 110.

It can be understood that the power supply 110 is generally commercial power.

The ballast detection module 220 detects whether the ballast 120 is connected to the power supply circuit 200, so as to determine if the PFC module 230 should be turned on. When the ballast 120 is connected to the power supply circuit 200, the PFC module 230 does not have substantial contribution to the power factor correction of the circuit itself. At this time, turning off the PFC module 230 can avoid damage caused by the high voltage generated by the ballast 120 to the PFC module 230 during start phase, and can reduce the loss of the PFC module 230.

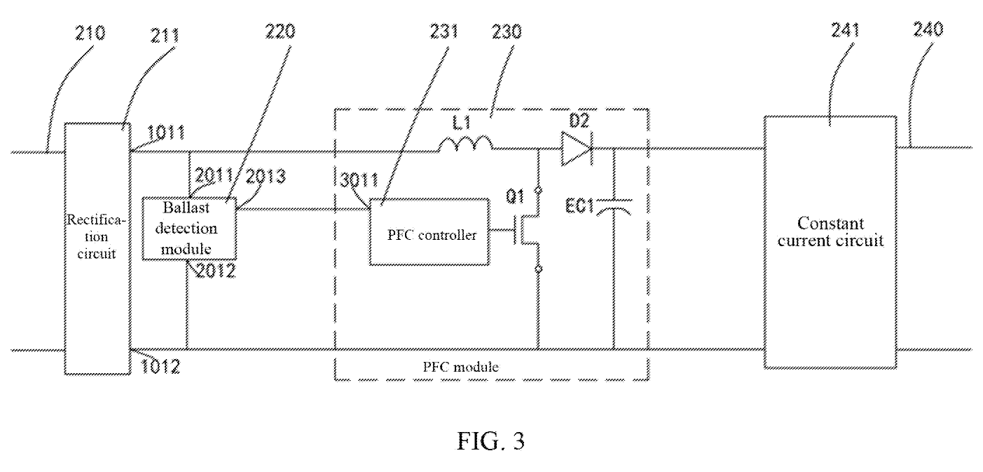

Referring to FIG. 3, the PFC module 230 includes a PFC controller 231, an inductor L1, a diode D2, a buffer capacitor EC1, and a field effect transistor Q1.

The input end of the rectification circuit 211 is connected to the power supply 110, one output end 1011 of the rectification circuit 211 is connected to one input end 2011 of the ballast detection module 220, and the other output end 1012 of the rectification circuit 211 is connected to the other input end 2012 of the ballast detection module 220. One output end 2013 of the ballast detection module 220 is connected to an input end of the PFC controller 231, and the other input end 3011 of the PFC controller 231 is connected to the other input end of the ballast detection module 220, and the output end of the PFC controller 231 is connected to the gate of the field effect transistor Q1. One output end 1011 of rectification circuit 211 and one input end 2011 of ballast detection module 220 are connected to one end of inductor L1, the other end of inductor L1 is connected to the drain of field effect transistor Q1 and the anode of diode D2. The cathode of diode D2 is connected to one end of snubber capacitor EC1 and one input end of the constant current circuit 241. One output end 1011 of rectification circuit 211 is connected to the source of the field effect transistor Q1, the other end of snubber capacitor EC1 and the other input end of the constant current circuit 241. The output end of the constant current circuit 241 is connected to the load 130.

It can be appreciated that, the PFC module 230 being in an inactive state means that the switching element Q1 is always in an off state rather than an on-off state, so that no current flows through the PFC module. The PFC module 230 being in an active state means that the switching element Q1 is in an on-off state, so that a high-frequency DC current can flow through the PFC module.

The input port 210 is generally the L and N lines of the power supply, or the output end of the ballast. The input port 210 is connected to a rectification circuit 211, the rectification circuit 211 is configured to convert alternating current into direct current. Specifically, the rectification circuit 211 is a rectifier bridge formed by connecting the positive and negative poles of four diodes end to end. The rectifier bridge is connected to mains supply so as to convert alternating current of the mains supply into direct current.

The output port 240 is generally connected to LEDs or other loads. The output port 240 is connected to a dimming circuit. By changing the voltage and current of the power supply 110 or using PWM, etc., the dimming circuit adjusts the brightness of the light source to meet different lighting needs. When the user does not need full brightness lighting, the dimming circuit reduces energy consumption by reducing the brightness of the light source to achieve the purpose of energy saving. The output port 240 is connected to a constant current circuit 241 through which the current output to the lamp is stabilized.

In an embodiment, the ballast detection module 220 includes a filter unit 2211 and a first comparison unit U4, both ends of the filter unit 2211 are connected to the input port 210 and the first comparison unit U4 respectively, the filter unit 2211 is configured to filter an input electrical signal of the input port 210 to obtain a filtered electrical signal, the first comparison unit U4 is configured to compare the filtered electrical signal and the input electrical signal to obtain a first comparison signal, and the first comparison signal is configured to indicate whether the ballast 120 is connected to the power supply circuit 200.

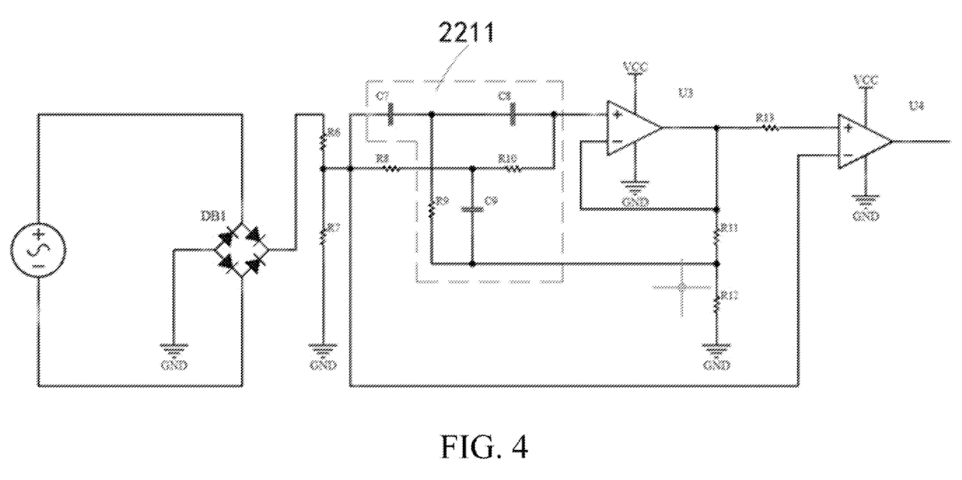

Referring to FIG. 4, the input end of the filter unit 2211 is connected to the input port 210, and the output end of the filter unit 2211 is connected to a forward input end of the harmonic amplifier U3. The harmonic amplifier U3 is used for amplifying the filtered electrical signal output by the filter unit 2211. A reverse input end of the harmonic amplifier U3 is connected to an output end of the harmonic amplifier U3.

Specifically, the filter unit 2211 is a double-T band stop filter composed of a seventh capacitor C7, an eighth capacitor C8, a ninth capacitor C9, a ninth resistor R9 and a tenth resistor R10. The operational amplifier U3 follows and amplifies the filtered electrical signal filtered by the filter unit 2211. By designing the parameters of the capacitor and resistor of the filter unit 2211, the filter unit 2211 can be made to filter the fundamental wave signal from 100 Hz to 120 Hz. Since the voltage or current connected to the ballast 120 contains a large number of high-order harmonics, when the ballast 120 is connected to power supply circuit 200, the filter unit 2211 filters the fundamental signal, such that the filtered electrical signal filtered by the filter unit 2211 basically contains a high-order harmonics signal. By detecting the ratio of the signals before and after filtering by the first comparison unit U4, it can be determined whether the ballast 120 is connected to the power supply circuit 200.

When the filtered electrical signal is greater than the proportional threshold of the input electrical signal, it is determined that the ballast 120 is connected to the power supply circuit 200; otherwise, it is determined that no ballast 120 is connected to the power supply circuit 200. After the input port 210 is connected to the mains supply by connecting with the ballast 120, the input electrical signal output by the input port 210 contains a large number of high-order harmonics after passing through waveforms output by the ballast 120. The proportional threshold can be set to 10% of the fundamental wave. Based on whether the filtered electrical signal, which basically contains high-order filtering, is greater than 10% of the fundamental wave, it can be quickly determined whether the ballast 120 is connected to the power supply circuit 200. When the filtered electrical signal is greater than 10% of the input electrical signal, a first comparison signal indicating that the ballast 120 is connected to the power supply circuit 200 is obtained. When the filtered electrical signal is less than or equal to 10% of the input electrical signal, a first comparison signal indicating that no ballast 120 is connected to the power supply circuit 200 is obtained.

In an embodiment, the ballast detection module 220 includes a first peak detection unit 2222, an integration unit 2221 and a second comparison unit U2. Both ends of the first peak detection unit 2222 is connected to the input port 210 and the second comparison unit U2 respectively. Both ends of the integration unit 2221 are connected to the input port 210 and the second comparison unit U2 respectively. The first peak detection unit 2222 is configured to detect a first peak value of the input electrical signal of the input port 210. The integration unit 2221 is configured to integrate the input electrical signal of the input port 210 to obtain a first integrated value. The second comparison unit U2 is configured to compare the first peak value with the first integrated value to obtain a second comparison signal, and the second comparison signal is configured to indicate whether the ballast 120 is connected to the power supply circuit 200.

In an embodiment, when the first integrated value is greater than 0.707 of the first peak value, then it is determined that the ballast 120 is connected to the power supply circuit 200; otherwise, it is determined that no ballast 120 is connected to the power supply circuit 200. For a sine wave, the waveform factor of the sine wave (the ratio of the effective value of the periodic waveform to the average value of the waveform) is 1.1, and the peak factor of the sine wave (the ratio of the peak value of the periodic waveform to the effective value) is 1.414. For the ballast 120, the waveform factor of the output waveform is required to be less than 2.2, usually around 1.5. Due to the constant current effect of the ballast 120, its peak voltage is generally less than the effective value of 1.414. After the ballast 120 is connected to the power supply circuit 200, the ratio of the effective value to the peak value of the output waveform is greater than 0.707, and thus 0.707 is used as the benchmark for judging whether the ballast 120 is connected to the power supply circuit 200.

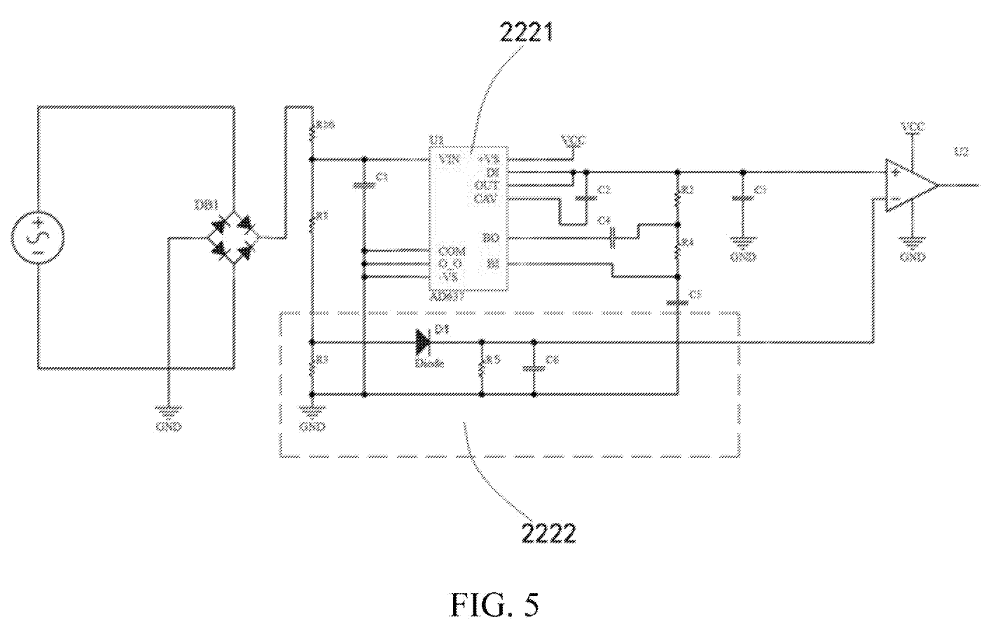

Referring to FIG. 5, the integration unit 2221 includes the AD637 chip U1 through which is integrated. The VIN pins of the AD637 chip U1 are connected to the power supply 110 through the sixteenth resistor R16 for collecting the signal of the power supply 110. At the same time, a first capacitor C1 is also connected between the VIN pins and VS pins of the AD637 chip U1. The signal output end of the AD637 chip U1 is connected to the forward input end of the second comparison unit U2, and outputs the first integrated value of input electrical signal of the input port 210 to the second comparison unit U2. In other embodiments, the integration unit 2221 can also use other circuits with integral calculation functions or other types of chips.

The output end of the input port 210 is connected to the first peak detection unit 2222. The first peak detection unit 2222 is composed of a first diode D1 and a sixth capacitor C6. The anode of the first diode D1 is connected to the output end of the input port 210. The cathode of the first diode D1 is connected to one end of the sixth capacitor C6 and the reverse input end of the second comparison unit U2, respectively. The other end of the sixth capacitor C6 is connected to the ground. The first peak detection unit 2222 outputs the first peak value of the input electrical signal of the input port 210 to the second comparison unit U2.

The forward input end of the second comparison unit U2 receives the first integrated value of the input electrical signal of the input port 210, and the reverse input end of the second comparison unit U2 receives the first peak value of the input electrical signal of the input port 210. The second comparison unit U2 compares the two signals to determine whether the first integrated value of the input electrical signal is greater than 0.707 of the first peak value of the input electrical signal of the input port 210, and then determine whether the ballast 120 is connected to the output end of the power supply 110. Specifically, when the first integrated value is greater than 0.707 of the first peak value, a second comparison signal indicating that the ballast 120 is connected to the power supply circuit 200 is obtained. When the first integrated value is less than or equal to 0.707 of the first peak value, a second comparison signal indicating that no ballast 120 is connected to the power supply circuit 200 is obtained.

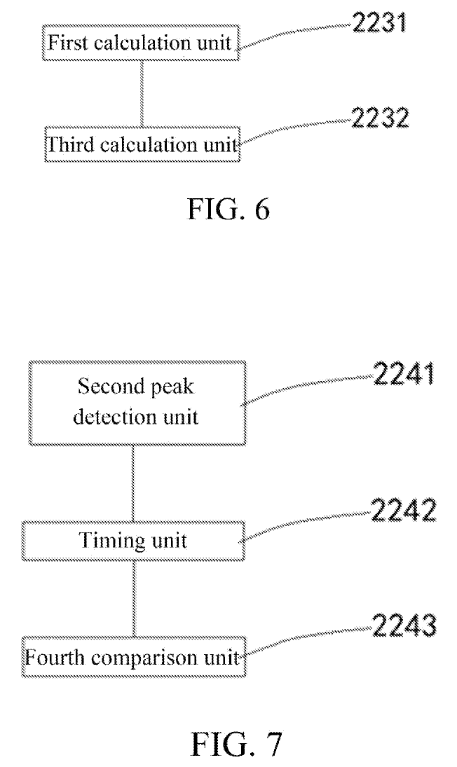

In an embodiment, referring to FIG. 6, the ballast detection module 220 includes a first calculation unit 2231 and a third comparison unit 2232. The first calculation unit 2231 is configured to perform Fourier calculation on a sampling signal of the input electrical signal of the detection input port 210 to obtain a harmonic content proportion value. The third comparison unit 2232 is configured to compare the harmonic content proportion value with a preset first threshold to obtain a third comparison signal, and the third comparison signal is configured to indicate whether the ballast 120 is connected to the power supply circuit 200.

In an embodiment, the input electrical signal of the input port 210 is sampled by the sampling circuit to obtain the sampled signal, the Fourier calculation is performed on the sampled signal of the input electrical signal of the input port 210 by the first calculation unit 2231 to obtain a harmonic content proportion value, and the numerical relationship between the harmonic content proportional value and the preset first threshold is obtained by the third comparison unit 2232. The first threshold is set to 10%. When the harmonic content proportion value is greater than 10%, a third comparison signal indicating that the ballast 120 is connected to the power supply circuit 200 is obtained. When the harmonic content proportion value is less than or equal to 10%, a third comparison signal indicating that no ballast 120 is connected to the power supply circuit 200 is obtained.

In an embodiment, referring to FIG. 7, the ballast detection module 220 includes a second peak detection unit 2241, a timing unit 2242 and a fourth comparison unit 2243. The second peak detection unit 2241 is configured to detect the second peak value of the input electrical signal of the input port 210. The timing unit 2242 is configured to calculate a duration of the second peak value. The fourth comparison unit 2243 is configured to compare the duration with a preset second threshold to obtain a fourth comparison signal, and the fourth comparison signal is configured to indicate whether the ballast 120 is connected to the power supply circuit 200.

In an embodiment, the input electrical signal of the input port 210 is sampled by the sampling circuit to obtain a sampling signal, the second peak value of the input electrical signal of the input port 210 is detected by the second peak detection unit 2241, and the duration of the second peak value is calculated by the timing unit 2242. The duration of the second peak is defined as starting from when the voltage reaches 0.95 of the highest voltage and ending when the voltage drops or rises to 0.95 of the highest voltage. The fourth comparison signal is obtained by comparing the duration with the preset second threshold through the fourth comparison unit 2243. The second threshold is set to 2 milliseconds. When the duration is greater than 2 milliseconds, a fourth comparison signal indicating that the ballast 120 is connected to the power supply circuit 200 is obtained. When the duration is less than or equal to 2 milliseconds, a fourth comparison signal indicating that no ballast 120 is connected to the power supply circuit 200 is obtained.

The ballast detection module 220 can be implemented through a micro controller unit (MCU), for example, through a microcontroller, ARM processor or FPGA.

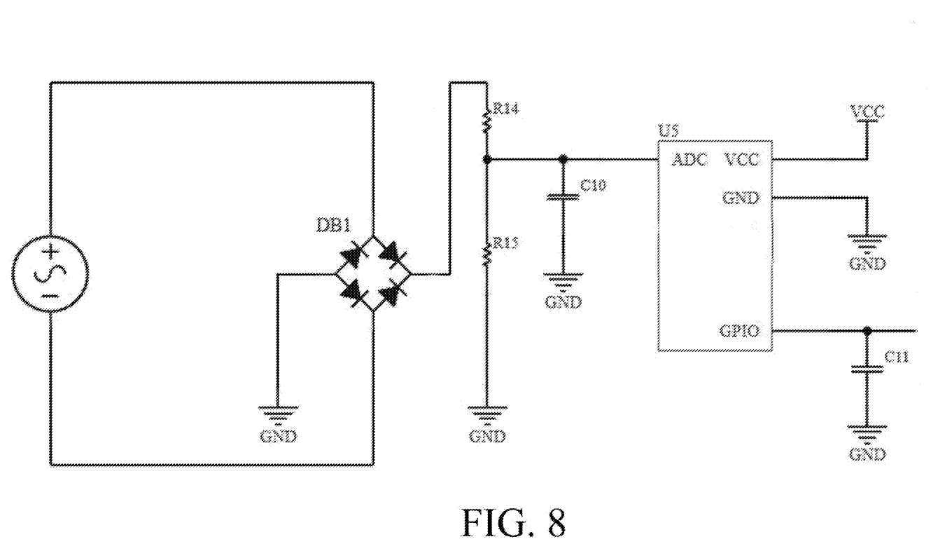

Referring to FIG. 8, the micro control unit a microcontroller U5, and the microcontroller U5 includes a first pin ADC, a second pin GPIO and a third pin GND. The first pin ADC receives the control signal generated by the detection module and controls the on/off of the second pin GPIO and the third pin GND according to the control signal. The second pin GPIO is connected to the PFC module 230, and the third pin GND of the control module is connected to ground.

The ballast detection module 220 further includes an NPN type transistor. When detecting that the ballast 120 is connected to the power supply circuit 200, the ballast detection module 220 transmits a high-level signal to the base electrode of transistor Q1, causing the collector and emitter of transistor Q1 to conduction, grounding the PFC unit, thereby turning off the PFC module 230 to be in an inactive state; otherwise, a low-level signal is transmitted to the base electrode of transistor Q1 to turn on the PFC module 230 to be in an active state.

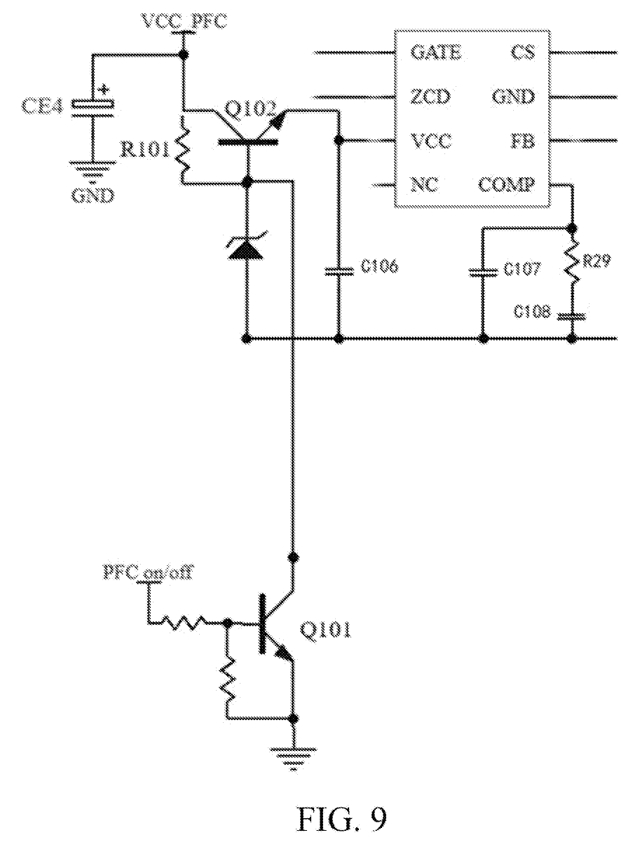

Referring to FIG. 9, the output end of the ballast detection module 220 is connected to the input end of the power supply 110 of the PFC module 230. When detecting that the ballast 120 is connected to the power supply circuit 200, the output end of the ballast detection module 220 outputs the first control level to power off the power input end of the PFC module 230 to turn off the PFC module 230 to be in an inactive state. The shutdown of the PFC module 230 is controlled by controlling the power supply of the PFC module 230, where the PFC module 230 includes a transistor Q101 and a transistor Q102, and the transistor Q101 and the transistor Q102 are both NPN type transistors. The base electrode of transistor Q101 is connected to the detection module and receives the control signal from the detection module. The collector of transistor Q101 is connected to the base electrode of transistor Q102. The emitter of transistor Q101 is grounded. The transistor Q101 is configured to control whether the base electrode of transistor Q102 is grounded. The base electrode of transistor Q102 is connected to the collector of transistor Q101. The collector of transistor Q102 is connected to the power supply 110 of the PFC module 230. The emitter of transistor Q102 is connected to the VCC pins of the chip in the PFC module 230. When the base electrode of transistor Q101 receives a high-level signal from the detection module, the transistor Q101 is in conduction to cause the base electrode of the transistor Q102 to be grounded through the transistor Q101. Then, the transistor Q102 is turned off, such that the power supply 110 of the PFC module 230 cannot supply power for the PFC module 230 through the transistor Q102, thus realizing the shutdown of the PFC module 230.

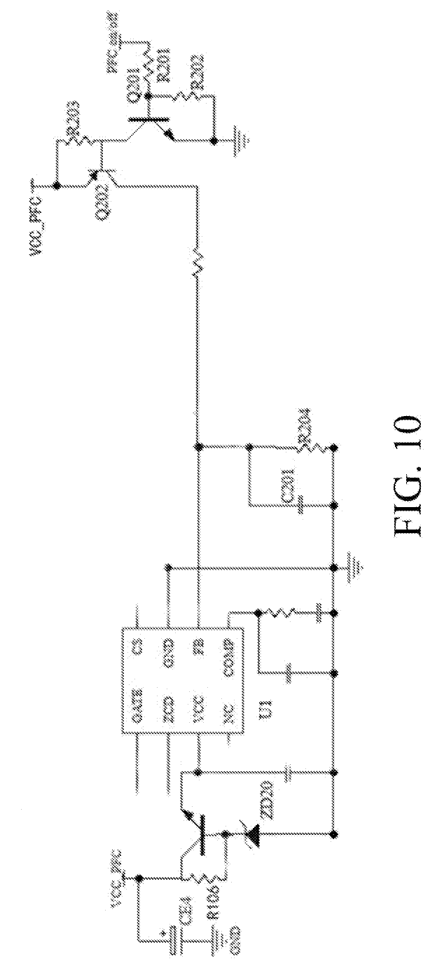

Referring to FIG. 10, the output end of the ballast detection module 220 is connected to the feedback end of the PFC module 230. When detecting that the ballast 120 is connected to the power supply circuit 200, the output end of the ballast detection module 220 outputs the second control level to change the voltage of the feedback end of the PFC module 230 to turn off the PFC module 230 to be in an inactive state. By changing the voltage at the feedback end of the PFC module 230, the PFC module 230 stops working. The ballast detection module 220 includes a transistor Q201 and a transistor Q202, and the transistor Q201 and the transistor Q202 are both NPN transistors. The feedback end of the PFC module 230 is the FB pin of the chip in the PFC module 230. The base electrode of transistor Q201 is connected to the detection module. The collector of transistor Q201 is connected to the base electrode of transistor Q202. The emitter of transistor Q201 is connected to ground. The collector of transistor Q202 is connected to the feedback end of the chip in the PFC module 230. The emitter of transistor Q202 is connected to the feedback end of the chip in the PFC module 230. When the base electrode of transistor Q201 receives a high-level signal from the detection module, the transistor Q201 is in conduction. The base electrode of transistor Q202 is grounded through the transistor Q201, and the transistor Q202 is turned off to cancel the connection between the PF pins of the control chip and the feedback end. By changing the voltage at the feedback end of the PFC module 230, the PFC module 230 thus stops working.

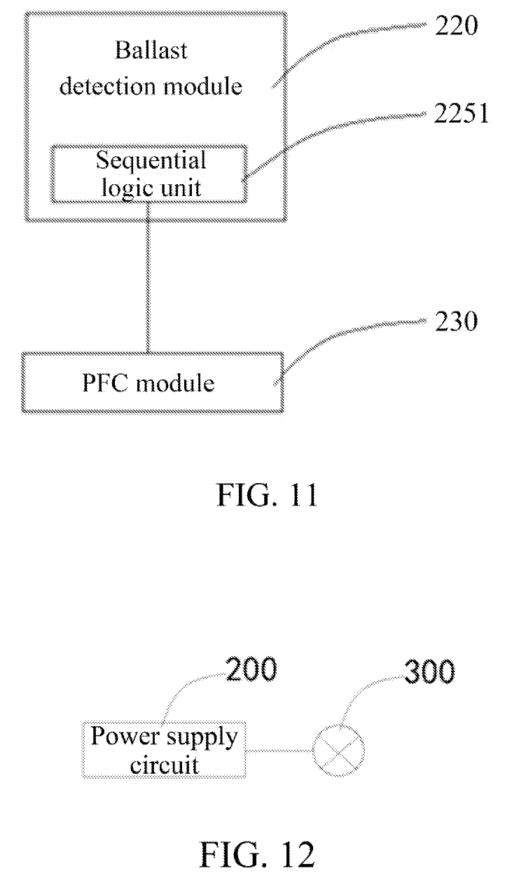

Referring to FIG. 11, the ballast detection module 220 includes a sequential logic unit 2251 connected to the PFC module 230, the sequential logic unit 2251 is configured to output a start timing signal in response to receiving a power-on signal, and the start timing signal is configured to control a start time of the PFC module 230

Specifically, in the initial powering stage of the power supply circuit 200, the PFC module 230 does not work. For example, in the initial powering stage of the power supply circuit 200, the sequential logic unit 2251 outputs the start timing signal. The first part of the start timing signal is of low level, and the PFC module 230 does not start when it receives a low-level start timing signal. The last part of the start sequence signal is of high level, and the PFC module 230 starts when it receives a high level start timing signal.

The PFC module 230 is provided with a buffer capacitor EC1 configured to clamp the voltage output by the ballast 120 when the ballast 120 is connected to the power supply circuit 200. In the initial powering stage, the ballast 120 will output a high voltage. The buffer capacitor EC1 absorbs the high voltage and buffers the high voltage output by the ballast 120, reducing damage to the PFC module 230.

An embodiment of the present disclosure provides a lamp. Referring to FIG. 12, the lamp includes a light source 300 and the above power supply circuit 200, and the light source 300 is connected to an output port 240 of the power supply circuit 200.

The above is a detailed description of the preferred implementation of the present disclosure, but the present disclosure is not limited to the embodiments. Those skilled in the art can make various equivalent modifications or substitutions without departing from the gist of the present disclosure. These equivalent modifications or substitutions are included in the scope defined by the claims of the present disclosure.

What is claimed is:

1. A power supply circuit, comprising:
an input port configured to be connected to a power supply;
an output port configured to be connected to a load;
a power factor correction (PFC) module, both ends of the PFC module being connected to the input port and the output port respectively; and
a ballast detection module connected to the PFC module, the ballast detection module being configured to turn off the PFC module to be in an inactive state in response to detecting that a ballast is connected to the power supply circuit, and turn on the PFC module to be in an active state in response to detecting that no ballast is connected to the power supply circuit.

2. The power supply circuit according to claim 1, wherein the ballast detection module comprises a filter unit and a first comparison unit, both ends of the filter unit are connected to the input port and the first comparison unit respectively, the filter unit is configured to filter an input electrical signal of the input port to obtain a filtered electrical signal, the first comparison unit is configured to compare the filtered electrical signal with the input electrical signal to obtain a first comparison signal, and the first comparison signal is configured to indicate whether the ballast is connected to the power supply circuit.

3. The power supply circuit according to claim 1, wherein the ballast detection module comprises a first peak detection unit, an integration unit and a second comparison unit, both ends of the first peak detection unit are connected to the input port and the second comparison unit respectively, both ends of the integration unit are connected to the input port and the second comparison unit respectively, the first peak detection unit is configured to detect a first peak value of an input electrical signal of the input port, the integration unit is configured to integrate the input electrical signal of the input port to obtain a first integrated value, the second comparison unit is configured to compare the first peak value with the first integrated value to obtain a second comparison signal, and the second comparison signal is configured to indicate whether the ballast is connected to the power supply circuit.

4. The power supply circuit according to claim 1, wherein the ballast detection module comprises a first calculation unit and a third comparison unit, the first calculation unit is configured to perform Fourier calculation on a sampling signal of an input electrical signal of the detection input port to obtain a harmonic content proportion value, the third comparison unit is configured to compare the harmonic content proportion value with a preset first threshold to obtain a third comparison signal, and the third comparison signal is configured to indicate whether the ballast is connected to the power supply circuit.

5. The power supply circuit according to claim 1, wherein the ballast detection module comprises a second peak detection unit, a timing unit and a fourth comparison unit, the second peak detection unit is configured to detect a second peak value of an input electrical signal of the input port, the timing unit is configured to calculate a duration of the second peak value, the fourth comparison unit is configured to compare the duration with a preset second threshold to obtain a fourth comparison signal, and the fourth comparison signal is configured to indicate whether the ballast is connected to the power supply circuit.

6. The power supply circuit according to claim 1, wherein an output end of the ballast detection module is connected to a power input end of the PFC module, and in response to detecting that the ballast is connected to the power supply circuit, the output end of the ballast detection module outputs a first control level to turn off the PFC module to be in an inactive state.

7. The power supply circuit according to claim 1, wherein an output end of the ballast detection module is connected to a feedback end of the PFC module, and in response to detecting that the ballast is connected to the power supply circuit, the output end of the ballast detection module outputs a second control level to change a voltage of the feedback end of the PFC module to turn off the PFC module to be in an inactive state.

8. The power supply circuit according to claim 1, wherein the ballast detection module comprises a sequential logic unit connected to the PFC module, the sequential logic unit is configured to output a start timing signal in response to receiving a power-on signal, and the start timing signal is configured to control a start time of the PFC module.

9. The power supply circuit according to claim 8, wherein the PFC module is provided with a buffer capacitor, and the capacitor is configured to clamp a voltage output by the ballast in response to the ballast being connected to the power supply circuit.

10. A lamp, comprising a light source and the power supply circuit according to claim 1, wherein the light source is connected to an output port of the power supply circuit.
